(19) United States
(12) Patent Application Publication
(10) Pub. No.: US 2007/0040285 A1
(43) Pub. Date: Feb. 22, 2007

(54) Heat dissipating grease

(75) Inventor: Bor-Yuan Hsiao, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/473,988

(22) Filed: Jun. 23, 2006

(30) Foreign Application Priority Data
Aug. 19, 2005 (CN) 200510036757.7

(51) Int. Cl. H01L 23/29

(52) U.S. Cl. 257/789

(57) ABSTRACT

A heat dissipating grease includes a polymer matrix and a plurality of heat conducting fillers incorporated thereinto. A thermal conductivity of the polymer matrix is 0.1˜0.2 W/mK. A thermal conductivity of the heat conducting filler is 20˜1000 W/mK. A weight ratio of the polymer matrix and the heat conducting filler is in a range from 1/7 to 1/3.

### TECHNICAL FIELD

The present invention generally relates to thermal interface materials, and more particularly to a heat dissipating grease.

### BACKGROUND

Electronic components such as semiconductor chips are becoming progressively smaller, while at the same time heat dissipation requirements are increasing. Commonly, a thermal interface material is used between the electronic component and a heat sink in order to efficiently dissipate heat generated by the electronic component.

A variety of heat dissipating thermally conductive materials have been proposed, and they are available in two forms: (1) sheets that are easy to handle and (2) pastes commonly referred to as heat dissipating greases. The heat dissipating greases mentioned above offer advantages of being able to fill irregular surfaces and crevices in electronic elements and enlarging a contact area between the electronic elements and the heat dissipating materials. To some extent, the enlarged contact area enable the heat dissipating grease to perform a better heat dissipating function. But a thermal impedance of the heat dissipating greases is another important factor affecting the heat dissipation efficiency. However, in designing or manufacturing the heat dissipating greases, conventional techniques seldom pay attention to such factor.

Therefore, it is desired to provide an improved heat dissipating grease that overcomes the above-described problems.

### SUMMARY

A heat dissipating grease includes a polymer matrix and a plurality of heat conducting fillers incorporated thereinto. A thermal conductivity of the polymer matrix is 0.1˜0.2 W/mK. A thermal conductivity of the heat conducting filler is 20˜1000 W/mK. A weight ratio of the polymer matrix to the heat conducting filler is in a range from 1/7 to 1/3.

Advantages and novel features will become more apparent from the following detailed description when taken in conjunction with the accompanying drawing.

### BRIEF DESCRIPTION OF THE DRAWING

Many aspects of the present heat dissipating grease can be better understood with reference to the following drawing. The components in the drawing are not necessarily drawn to scale, the emphasis instead being placed upon clearly illustrating the principles of the present heat dissipating grease. Moreover, in the drawing, like reference numerals designate corresponding parts throughout the view.

FIG. 1 is a schematic graph, showing a relation between a weight ratio of zinc oxide to polyol ester and a thermal impedance regarding the corresponding weight ratio, in accordance with a preferred embodiment.

### DETAILED DESCRIPTION OF PREFERRED EMBODIMENT

In the following, the description of a preferred embodiment is in connection with a heat dissipating grease. The heat dissipating grease includes a polymer matrix and an amount of heat conducting filler incorporated in the polymer matrix. A thermal conductivity of the polymer matrix is about 0.1˜0.2 W/mK. A thermal conductivity of the heat conducting filler is about 20˜1000 W/mK. In the heat dissipating grease, the content of the polymer matrix is 100 parts by weight, and the content of the heat conducting filler is in the range from 300 to 700 parts by weight. That is, a weight ratio of the polymer matrix to the heat conducting filler is in a range from 1/3 to 1/7. Preferably, a weight ratio of the polymer matrix to the heat conducting filler is about 1:4.

The polymer matrix is comprised of polyol ester. The heat conducting filler is comprised one of zinc oxide, aluminum nitrogen, silicon carbide, and any combination thereof. The heat conducting filler may be spherical, ellipsoid or capsule-shaped. A diameter of the heat conducting filler is less than 1 micrometer, for example, in a range from 0.5 micrometers to 1 micrometer. Preferably, the heat conducting fillers have a uniform diameter and are uniformly dispersed in the polymer matrix. In addition, in the practice of the present embodiment, various additives may be added, if necessary.

A method for manufacturing the above heat dissipating grease includes steps of: providing a polymer matrix having a thermal conductivity of 0.1˜0.2 W/mK; providing a heat conducting filler having a thermal conductivity of 20˜1000 W/mK; and mixing the polymer matrix and the heat conducting filler in a weight ratio from 1/7 to 1/3.

According to above method, uses polyol ester as the polymer matrix and using zinc oxide as the heat conducting filler, makes a heat dissipating grease. Adjusting the weight ratio of the polyol ester to zinc oxide, different varieties of the desired heat dissipating greases can be manufactured. In the following example, five groups of heat dissipating greases are made and their thermal impedances are measured for comparison.

A first variety of heat dissipating grease can be made as follows: providing four grams of zinc oxide and two grams of polyol ester; mixing the zinc oxide and the polyol ester and blending the mixture for 1˜2 hours, then obtaining the first heat dissipating grease G₁. Similarly, a second variety of heat dissipating grease can be made as follows: providing three grams of zinc oxide and one gram of polyol ester; mixing the zinc oxide and the polyol ester and blending the mixture for 1˜2 hours to get the second heat dissipating grease G₂. A third variety of heat dissipating grease can be made as follows: providing eight grams of zinc oxide and two grams of polyol ester; mixing the zinc oxide and the polyol ester and blending the mixture for 1˜2 hours to get a third heat dissipating grease G₃. A fourth variety of heat dissipating grease can be made as follows: providing ten grams of zinc oxide and two grams of polyol ester; mixing the zinc oxide and the polyol ester and blending the mixture for 1˜2 hours to get a fourth heat dissipating grease G₄. A fifth variety of heat dissipating grease can be made as follows: providing six grams of zinc oxide and one grams of polyol ester; mixing the zinc oxide and the polyol ester and blending the mixture for 1˜2 hours to get a fifth heat dissipating grease G₅.

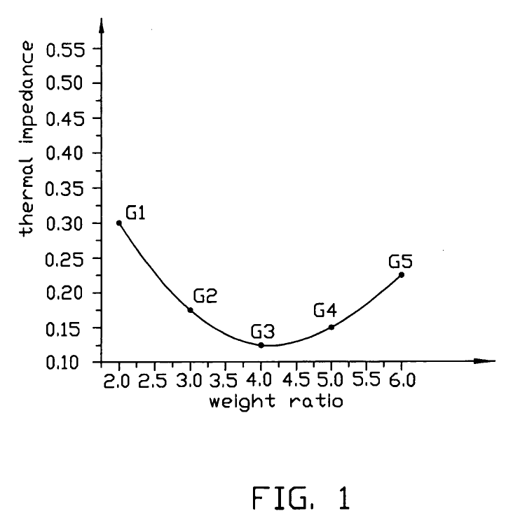

Thermal impedance of each of the five heat dissipating greases G₁, G₂, G₃, G₄ and G₅ was measured, the measured thermal impedance of the heat dissipating greases G₁, G₂, G₃, G₄ and G₅ respectively was about 0.300, 0.175, 0.125, 0.150 and 0.225. Referring to FIG. 1, a graph is shown in which the abscissa represents the weight ratio of zinc oxide to the polyol ester, and the ordinate represents the thermal impedance regarding the corresponding weight ratio.

According to the FIG. 1, the thermal impedance of the heat dissipating grease is greatly affected by the weight ratio of zinc oxide to the polyol ester. For example, in a range from 2:1 to 4:1 of the weight ratio of zinc oxide to the polyol ester, with the increasing of the weight ratio, a value of the thermal impedance decreases. On the contrary, in a range from 4:1 to 7:1 of the weight ratio of zinc oxide to the polyol ester, with the increasing of the weight ratio, a value of the thermal impedance increases. Therefore, as the weight ratio of zinc oxide to the polyol ester is 4:1, the heat dissipating grease shows a less thermal impedance value, such heat dissipating grease has better heat dissipating efficiency.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipating grease, comprising:
a polymer matrix having a thermal conductivity of 0.1˜0.2 W/mK; and
a plurality of heat conducting fillers having a thermal conductivity of 20˜1000 W/mK incorporated into the polymer matrix;
wherein a weight ratio of the polymer matrix to the heat conducting filler is in a range from 1/7 to 1/3.

2. The heat dissipating grease as claimed in claim 1, wherein the weight ratio of the polymer matrix to the heat conducting fillers is about 1/4.

3. The heat dissipating grease as claimed in claim 1, wherein the polymer matrix is comprised of polyol ester.

4. The heat dissipating grease as claimed in claim 1, wherein a grain size of the heat conducting fillers is less than 1 micrometer.

5. The heat dissipating grease as claimed in claim 4, wherein the grain size of the heat conducting fillers is in a range from 0.5 micrometers to 1 micrometer.

6. The heat dissipating grease as claimed in claim 1, wherein the heat conducting fillers are comprised of a material selected from the group consisting of zinc oxide, aluminum nitride and silicon carbide.

7. The heat dissipating grease as claimed in claim 1, wherein the heat conducting fillers each has a shape selected from the group consisting of spherical, ellipsoid and capsule-shaped.
